(19) United States
(12) Patent Application Publication
(10) Pub. No.: US 2007/0224840 A1
(43) Pub. Date: Sep. 27, 2007

(54) Method of Plasma Processing with In-Situ Monitoring and Process Parameter Tuning

(75) Inventors: Anthony Renau, West Newbury, MA (US); Vikram Singh, North Andover, MA (US); Atul Gupta, Beverly, MA (US); Timothy Miller, South Hamilton, MA (US); Edwin Arevalo, Haverhill, MA (US); George Papasouliotis, Andover, MA (US); Yong Bae Jeon, Lexington, MA (US)

Correspondence Address: RAUSCHENBACH PATENT LAW GROUP, LLC, P.O. BOX 387, BEDFORD, MA, 01730, US

(73) Assignee: VARIAN SEMICONDUCTOR EQUIPMENT ASSOCIATES, INC., Gloucester, MA (US)

(21) Appl. No.: 11/687,822

(22) Filed: Mar. 19, 2007

Related U.S. Application Data
(60) Provisional application No. 60/784,242, filed on Mar. 21, 2006.

(51) Int. Cl. H01L 21/00; H01L 21/336; H01L 21/22; H01L 21/38

(52) U.S. Cl. 438/798; 438/306; 438/547

(57) ABSTRACT

A method of selecting plasma doping process parameters includes determining a recipe parameter database for achieving at least one plasma doping condition. The initial recipe parameters are determined from the recipe parameter database. In-situ measurements of at least one plasma doping condition are performed. The in-situ measurements of the at least one plasma doping condition are correlated to at least one plasma doping result. At least one recipe parameter is changed in response to the correlation so as to improve at least one plasma doping process performance metric.

### RELATED APPLICATION SECTION

This application claims priority to U.S. Provisional Patent Application Ser. No. 06/784,242, filed Mar. 21, 2006, entitled “Tuning a Plasma Doping Apparatus for Optimal Processing,” the entire application of which is incorporated herein by reference.

### BACKGROUND OF THE INVENTION

Plasma processing has been widely used in the semiconductor and other industries for many decades. Plasma processing is used for tasks such as cleaning, etching, milling, and deposition. More recently, plasma processing has been used for doping. Plasma doping is sometimes referred to as PLAD or plasma immersion ion implantation (PIII). Plasma doping systems have been developed to meet the doping requirements of some modern electronic and optical devices.

Plasma doping is fundamentally different from conventional beam-line ion implantation systems that accelerate ions with an electric field and then filter the ions according to their mass-to-charge ratio to select the desired ions for implantation. In contrast, plasma doping systems immerse the target in a plasma containing dopant ions and bias the target with a series of negative voltage pulses. The electric field within the plasma sheath accelerates ions toward the target thereby implanting the ions into the target surface.

Plasma doping systems for the semiconductor industry generally require a very high degree of process control. Conventional beam-line ion implantation systems that are widely used in the semiconductor industry have excellent process control during plasma doping and also excellent run-to-run process control. Conventional beam-line ion implantation systems provide highly uniform doping across the entire surface of state-of-the art semiconductor substrates. In general, the process control of plasma doping systems is not as good as conventional beam-line ion implantation systems.

Known plasma doping processes are optimized by obtaining data from various off-line experiments, analyzing that data, and then changing the recipe parameters in response to the analysis. The present invention relates to in-situ monitoring and optimization of plasma processing apparatus, such as plasma doping apparatus. In-situ monitoring and optimization can greatly improve process control of plasma doping apparatus.

### BRIEF DESCRIPTION OF THE DRAWINGS

The invention, in accordance with preferred and exemplary embodiments, together with further advantages thereof, is more particularly described in the following detailed description, taken in conjunction with the accompanying drawings. The drawings are not necessarily to scale, emphasis instead generally being placed upon illustrating principles of the invention.

FIG. 1 shows a flow chart of a method of plasma doping with in-situ monitoring and process parameter tuning according to the present invention.

### DETAILED DESCRIPTION

The present teachings will now be described in more detail with reference to exemplary embodiments thereof as shown in the accompanying drawings. While the present teachings are described in conjunction with various embodiments and examples, it is not intended that the present teachings be limited to such embodiments. On the contrary, the present teachings encompass various alternatives, modifications and equivalents, as will be appreciated by those of skill in the art. Those of ordinary skill in the art having access to the teachings herein will recognize additional implementations, modifications, and embodiments, as well as other fields of use, which are within the scope of the present disclosure as described herein.

For example, although the methods of improving process control of the present invention are described in connection with plasma doping, it should be understood that the methods of the present invention can be applied to any type of plasma process. Specifically, the methods of improving uniformity according to the present invention can also be applied to plasma processing systems including systems used for deposition, such as chemical and physical deposition, and systems used for etching including reactive ion etching and physical etching.

It should be understood that the individual steps of the methods of the present invention may be performed in any order and/or simultaneously as long as the invention remains operable. Furthermore, it should be understood that the apparatus of the present invention can include any number or all of the described embodiments as long as the invention remains operable.

In known plasma doping systems, plasma doping recipe parameters, such as plasma power, chamber pressure, gas flow rates, dose, uniformity, and energy are optimized by utilizing a design of experiment (DOE) approach. The term “recipe parameters” is defined herein to mean actual apparatus settings or operating parameters that change plasma doping conditions in the processing tool. The recipe parameters constitute a process or recipe for performing a particular processing operation (i.e. plasma doping operation).

The design of experiment approach includes performing various off-line measurements of wafer parameters, such as Rs (resistivity after anneal) and/or junction depth and abruptness before and after anneal. For example, measurements of resistivity can be made from simple probe measurements. Measurements of junction depths can be experimentally obtained from secondary ion mass spectrometry (SIMS) data. The data from the off-line measurements are then analyzed. The data can be analyzed by hand or by a computer program. For example, various commercially available software analysis tools can be used to analyze the data or an application specific data analysis program can be written by the user. Improved recipe parameters are then obtained from the data analysis.

The improved recipe parameters are then used to create improved processing conditions. No further improvement or optimization is performed using on-line or in-situ measurements of plasma doping conditions created by the fixed recipe parameters. The term “in-situ measurements” is defined herein to mean any measurements of plasma doping conditions that are performed while processing wafers or other work pieces. This type of optimization is sometimes referred to as “open-loop optimization” because measurements of current plasma doping conditions are not used to dynamically modify the recipe parameters during plasma doping operation.

Open-loop optimization is prone to less than optimal tool operation for many reasons. For example, the plasma doping conditions in known open-loop plasma processing systems tend to drift over time because the chamber conditions and plasma properties tend to vary as a function of time. Known plasma doping, plasma enhanced chemical vapor deposition (PECVD), and plasma etching systems attempt to compensate for such changes in chamber and plasma properties by periodically cleaning and/or conditioning the process chamber.

Chamber cleaning and conditioning procedures are used to effectively reset the plasma chamber conditions to some initial conditions after some metric of processing time has elapsed, such as after a predetermined number of wafers have been processed. The sensitivity of the wafer level results to changes in the plasma chamber conditions determines the cleaning and conditioning intervals. Determining the maximum cleaning and/or conditioning interval are important for maximizing the overall tool throughput and process repeatability. Periodically cleaning and/or conditioning the process chamber, however, will reduce wafer throughput and increase total processing cost. In addition, it is desirable to compensate for tool idle by conditioning, which also negatively impact tool availability for productive processing.

Advanced semiconductor manufacturing processes often require tight process controls. In particular, plasma doping processes for fabricating advanced semiconductors require very precise control of implant dose and species mix within each wafer, wafer-to-wafer, and batch-to-batch. The periodic cleaning and/or conditioning of the process chamber may not be acceptable for these applications because recipe parameters may drift between the cleaning steps.

The methods according to the present invention perform closed-loop tuning of recipe parameters in order to adjust the plasma doping conditions in order to stabilize and/or improve the processing tool performance in some way. The term “closed-loop tuning of recipe parameters” is defined herein to mean the use of in-situ measurements to provide data on current operating conditions, which is used to adjust recipe parameters during processing. In some embodiments, methods of the present invention perform closed-loop tuning of recipe parameters to adjust the plasma doping conditions in order to optimize one or a plurality of processing conditions. In addition, in some embodiments, methods of the present invention perform closed-loop tuning of recipe parameters to adjust the plasma doping conditions in order to improve process tool cost metrics, such as process tool throughput and/or utilization.

For example, in some embodiments, methods of the present invention perform recipe parameters selection or optimization that provides for process improvements, such as higher (or highest) wafer throughput (wafer/hour), high (or highest) retained dose, uniformity across wafer and/or any other process parameter derived from the user's requirements. In some specific embodiments, the methods of the present invention optimize the process tool for certain customer requirements, such as angle dose control. Angle dose control is important for many applications. For example, angle dose control must be relatively high for conformal doping applications and must be relatively narrow for some other applications, such as source drain extensions (SDE).

More specifically, in some embodiments of the present invention, a method of optimizing a plasma process according to the present invention includes using a model-based recipe parameter generator to select initial recipe parameters. The term “model-based recipe parameter generator” is defined herein to mean any means of calculating recipe parameters based upon a numerical or a rule based method. In-situ measurements are taken under the current operating conditions. The in-situ measurements are then analyzed and correlated to at least one process result. One or more of the recipe parameters are then adjusted or “tuned” in response to a correlation of the in-situ measurements to at least one plasma doping result in order to improve or optimize the process. These improved or optimized recipe parameters are chosen to achieve a desired result, such as a higher level of process repeatability, a higher level of dose loop, and/or an improvement or optimization of system throughput and utilization. In many embodiments, this method is a non-linear optimization method.

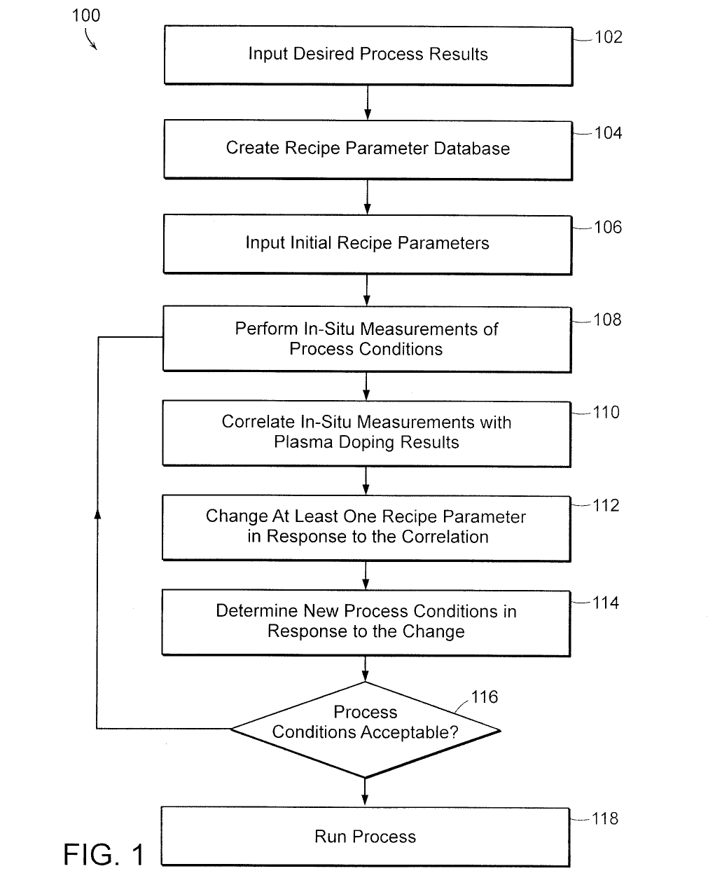

FIG. 1 shows a flow chart 100 of a method of plasma doping with in-situ monitoring and process parameter tuning according to the present invention. In some embodiments, the method performs in-situ monitoring and process parameter tuning to achieve improved process performance and/or improved process cost metrics. In other embodiments, the method performs in-situ monitoring and process parameter tuning to optimize at least one process performance metric and/or process cost metric.

In the first step 102, the desired process results are input by the user. For a plasma doping process, the desired process results includes wafer level implantation parameters, such as the implantation dose, implant energy, minimum uniformity, doping species, sheet resistance (as implanted), and annealed junction depth profile abruptness (as implanted). Typically, the annealed junction depth profile is characterized by the junction depth and the junction abruptness.

In the second step 104, a recipe parameter database is created for the desired plasma processing results that were entered in the first step 102. In some embodiments, the method uses a model based recipe parameter generator to generate the recipe parameter database. In various other embodiments, the user directly inputs data into the recipe parameter database or one of several predetermined recipe parameters databases are used.

In some embodiments, the recipe parameter database is generated by first taking off-line measurements using the design of experiment approach. The term “off-line measurements” is defined herein as measurements that are taken after the termination of the process. Typically test wafers are processed and then removed from the processing apparatus to perform the off-line measurements. The off-line measurements are then used to determine the relationships between the various plasma processing tool parameters or settings and the process or wafer level results. In many embodiments, the relationship between the various plasma processing tool parameters and the process level results is stored in a computer database.

In the third step 106, the initial recipe parameters are entered or input from the recipe parameter database that was generated in the second step 104. An analysis of the relationships between the various plasma processing tool parameters and the processing results are used to determine the initial recipe parameters. The processing results are the wafer level results of the process. The plasma processing tool parameters are the actual processing tool settings used to generate and maintain the plasma and processing environment. These processing tool parameters or setting are either entered by hand or entered into a computer program. Examples of processing tool parameters that can be determined from the recipe parameter database are the RF power, chamber pressure, DC bias, dopant and dilution gas flows, DC pulse frequency and pulse length.

In some embodiments, the initial recipe parameters represent the user's best estimate for the recipe parameters that directly achieve the desired processing results. In other embodiments, the initial recipe parameters are parameters that are suitable for “tuning” using the methods of the present invention to efficiently converge to recipe parameters that improve or optimize the process results.

In some embodiments, the initial recipe parameters are established from the recipe parameter database using an analytical/statistical model which correlates the plasma operating conditions with the plasma doping results from various design of experiment and/or single variable tests. In other embodiments, the initial recipe parameters are established from previously optimized plasma doping conditions.

In the fourth step 108, the plasma doping conditions are monitored by performing in-situ sensor measurements. In-situ sensor measurements of the plasma doping conditions can be taken with numerous types of sensors, such as optical emission spectrometers, time of flight (TOF) analysis probes, Langmuir probes, mass and energy analyzers, Faraday cup sensors, and deposition/etch/dose monitors, such as reflectometers. The in-situ sensor measurements can also be used to triggering a termination of the process and the initiation of a clean/conditioning sequence.

In the fifth step 110, the data from the in-situ monitoring of the plasma doping conditions obtained in the fourth step 108 is correlated to at least one plasma doping result. The at least one plasma doping result is a wafer level result that characterizes the doping, such as resistivity, junction depth, and abruptness before and after anneal. The correlation includes interpreting the in-situ measurements of sensor data in response to the various recipe parameters. For example, a change in the ion composition of the plasma that is measured by a TOF sensor can be correlated with measurements of the total ion dose.

In the sixth step 112, at least one recipe parameter is changed in response to the correlation performed in the fifth step 110 so as to improve or optimize the plasma doping conditions by at least one cost metric or performance metric. In other words, in the sixth step 112, at least one of the recipe parameters is “tuned” to a new recipe parameter that is more desirable (i.e. that improves or optimizes at least one cost or performance metric) based upon the correlation performed in the fifth step 110. In various embodiments, the at least one recipe parameter is “tuned” to achieve certain customer requirements, such as achieving particular processing goals, maximizing tool throughput and utilization, and improving process repeatability.

In the seventh step 114, the new plasma doping conditions resulting from the change in the at least one recipe parameter that was performed in the sixth step 112 is determined.

In the eighth step 116, a decision is made regarding whether the new plasma doping conditions determined in the seventh step 114, which correspond to the at least one recipe parameter that was changed in the sixth step 112 in response to the correlation, are acceptable. In some embodiments, a decision is made regarding whether the new plasma doping conditions are optimized for at least one plasma doping parameter. If the decision in the eighth step 116 indicates that the recipe parameters are acceptable, then the method 100 is terminated and the plasma doping process can be run on the wafers in the ninth step 118.

However, if the decision in the eighth step 116 indicates that the recipe parameters are not acceptable, then the method 100 returns control to the fourth step 108, where the plasma doping conditions are again monitored by performing in-situ sensor measurements. The method 100 then repeats until the process is run in the ninth step 118. In this way, the method 100 described in connection with FIG. 1 actively “tunes” the recipe parameters in a non-linear manner to further improve or to optimize plasma doping conditions for a plasma doping or other wafer level result.

In various embodiments, the method of in-situ monitoring and process parameter selection described in connection with FIG. 1 can be used to tune any one of the recipe parameters separately or simultaneously with other or all recipe parameters. In one embodiment, each of a plurality of recipe parameters is set and then the method of in-situ monitoring and process parameter selection described in connection with FIG. 1 is used to individually tune recipe parameters to improve or to optimize the plasma doping conditions. In another embodiment, the method of in-situ monitoring and process parameter selection described in connection with FIG. 1 is used to simultaneously tune some or all recipe parameters to improve or to optimize the plasma doping conditions.

The method of in-situ monitoring and process parameter selection described in connection with FIG. 1 can be used to reduce or minimize equipment downtime due to cleaning and/or conditioning of the plasma chamber and thus can improve the tool utilization and throughput. In addition, the method of in-situ monitoring and process parameter selection described in connection with FIG. 1 can be used to compensate for drift in the plasma doping conditions and, thus can result in more stable plasma doping conditions that improve process repeatability.

### EQUIVALENTS

While the present teachings are described in conjunction with various embodiments and examples, it is not intended that the present teachings be limited to such embodiments. On the contrary, the present teachings encompass various alternatives, modifications and equivalents, as will be appreciated by those of skill in the art, may be made therein without departing from the spirit and scope of the invention.

What is claimed is:

1. A method of selecting plasma doping process parameters comprising:
a. determining a recipe parameter database for achieving at least one plasma doping result;
b. determining initial recipe parameters from the recipe parameter database;
c. performing in-situ measurements of at least one plasma doping condition;
d. correlating the in-situ measurements of the at least one plasma doping condition to at least one plasma doping result; and
e. changing at least one recipe parameter in response to the correlation so as to improve at least one plasma doping process performance metric.

2. The method of claim 1 wherein the recipe parameter database is determined by a design of experiment test.

3. The method of claim 1 wherein the recipe parameter database is determined by at least one single variable experiment.

4. The method of claim 1 further comprising repeating the steps of performing the in-situ measurements, correlating the in-situ measurements, and changing the at least one recipe parameter until a desired improvement of the at least one plasma doping process performance metric is achieved.

5. The method of claim 4 wherein the initial recipe parameters are chosen to be recipe parameters that efficiently converge to recipe parameters that result in the desired improvement of the at least one plasma doping process performance metric.

6. The method of claim 1 wherein the performing the in-situ measurements comprises performing at least one of optical emission spectrometry, time of flight (TOF) analysis, mass analysis, neutral composition analysis, ion energy analysis, dose analysis, and plasma property analysis.

7. The method of claim 1 wherein the at least one plasma doping process performance metric comprises plasma doping tool throughput.

8. The method of claim 1 wherein the at least one plasma doping process performance metric comprises plasma doping dose.

9. The method of claim 1 wherein the at least one plasma doping process performance metric comprises plasma doping uniformity.

10. The method of claim 1 wherein the at least one plasma doping process performance metric comprises plasma angle distribution.

11. The method of claim 1 wherein the changing the at least one recipe parameter in response to the correlation optimizes at least one plasma doping process performance metric.

12. The method of claim 1 wherein the changing the at least one recipe parameter in response to the correlation optimizes at least two plasma doping process performance metrics.

13. The method of claim 1 wherein the correlating the in-situ measurements of the at least one plasma doping condition to the at least one plasma doping result comprises correlating with an analytical model.

14. The method of claim 1 wherein the correlating the in-situ measurements of the at least one plasma doping condition to the at least one plasma doping result comprises correlating with a statistical model.

15. The method of claim 1 wherein the correlating the in-situ measurements of the at least one plasma doping condition to the at least one plasma doping result comprises correlating with data from design of experiment tests.

16. The method of claim 1 wherein the correlating the in-situ measurements of the at least one plasma doping condition to the at least one plasma doping result comprises correlating with data from single variable test results.

17. A method of optimizing at least one plasma doping process parameters comprising:
a. determining a recipe parameter database for optimizing at least one plasma doping result;
b. determining initial recipe parameters from the recipe parameter database;
c. performing in-situ measurements of at least one plasma doping condition;
d. correlating the in-situ measurements of the at least one plasma doping condition to at least one plasma doping result;
e. changing at least one recipe parameter in response to the correlation so as to improve at least one plasma doping process performance metric; and
f. repeating the steps of performing the in-situ measurements, correlating the in-situ measurements, and changing the at least one recipe parameter until at least one plasma doping process performance metric is optimized.

18. The method of claim 17 wherein the performing the in-situ measurements comprises performing at least one of optical emission spectrometry, time of flight (TOF) analysis, mass analysis, neutral composition analysis, ion energy analysis, dose analysis, and plasma property analysis.

19. The method of claim 17 wherein the least one plasma doping process performance metric comprises plasma doping tool throughput.

20. The method of claim 17 wherein the least one plasma doping process performance metric comprises plasma doping dose.

21. The method of claim 17 wherein the least one plasma doping process performance metric comprises plasma doping uniformity.

22. The method of claim 17 wherein the correlating the in-situ measurements of the at least one plasma doping condition to the at least one plasma doping result comprises correlating with an analytical model.

23. The method of claim 17 wherein the correlating the in-situ measurements of the at least one plasma doping condition to the at least one plasma doping result comprises correlating with a statistical model.

24. The method of claim 17 wherein the correlating the in-situ measurements of the at least one plasma doping condition to the at least one plasma doping result comprises correlating with data from design of experiment tests.

25. The method of claim 17 wherein the correlating the in-situ measurements of the at least one plasma doping condition to the at least one plasma doping result comprises correlating with data from single variable test results.

26. A method of simultaneously optimizing at least two plasma doping process parameters comprising:
a. determining a recipe parameter database for optimizing at least one plasma doping result;
b. determining initial recipe parameters from the recipe parameter database;
c. performing in-situ measurements of at least one plasma doping condition;
d. correlating the in-situ measurements of the at least one plasma doping condition to at least one plasma doping result;
e. changing at least two recipe parameter in response to the correlation so as to improve at least one plasma doping process performance metrics; and
f. repeating the steps of performing the in-situ measurements, correlating the in-situ measurements, and changing the at least two recipe parameter until at least one plasma doping process performance metric is optimized.
